(19) United States
(12) Patent Application Publication
(10) Pub. No.: US 2005/0141195 A1
(43) Pub. Date: Jun. 30, 2005

(54) Folded fin microchannel heat exchanger

(76) Inventors: Himanshu Pokharna, San Jose, CA (US); Ravi Prasher, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/749,643

(22) Filed: Dec. 31, 2003

(51) Int. Cl. H05K 7/20

(52) U.S. Cl. 361/699

(57) ABSTRACT

Folded fin microchannel heat exchangers for cooling integrated circuit (IC) dies and packages and cooling systems employing the same are disclosed. The heat exchangers include a folded fin enclosed within the heat exchanger thereby defining a plurality of microchannels. In one embodiment, a folded fin microchannel heat exchanger is operatively coupled to an IC die or IC package using fasteners and is thermally coupled to the IC die or an IC package using a thermal interface material. In other embodiments, a folded fin microchannel heat exchanger is operatively and thermally coupled to an IC die or an IC package using a thermal epoxy or a solderable material. The folded fin microchannel heat exchangers may be employed in a closed loop cooling system includes a pump and a heat rejecter. The folded fin microchannels are configured to support either a two-phase or a single-phase heat transfer process using a working fluid such as water.

### BACKGROUND

Integrated circuits such as microprocessors generate heat when they operate and frequently this heat must be dissipated or removed from the integrated circuit die to prevent overheating. This is particularly true when the microprocessor is used in a notebook computer or other compact device where space is tightly constrained and more traditional die cooling techniques such as direct forced air cooling are impractical to implement.

One technique for cooling an integrated circuit die is to attach a fluid-filled microchannel heat exchanger to the die. A typical microchannel heat exchanger consists of a silicon substrate in which microchannels have been formed using a subtractive microfabrication process such as deep reactive ion etching or electro-discharge machining. Typical microchannels are rectangular in cross-section with widths of about 100 μm and depths of between 100-300 μm. Fundamentally the microchannels improve a heat exchanger's coefficient of heat transfer by increasing the conductive surface area in the heat exchanger. Heat conducted into the fluid filling the channels can be removed simply by withdrawing the heated fluid.

Typically, the microchannel heat exchanger is part of a closed loop cooling system that uses a pump to cycle a fluid such as water between the microchannel heat exchanger where the fluid absorbs heat from a microprocessor or other integrated circuit die and a remote heat sink where the fluid is cooled. Heat transfer between the microchannel walls and the fluid is greatly improved if sufficient heat is conducted into the fluid to cause it to vaporize. Such “two-phase” cooling enhances the efficiency of the microchannel heat exchanger because significant thermal energy above and beyond that which can be simply conducted into the fluid is consumed in overcoming the fluid's latent heat of vaporization. For example, conductively heating 50 grams of liquid water from 0° C. to 100° C. consumes 21 kJ of heat energy while then vaporizing the same quantity of water at 100° C. consumes a further 113 kJ of energy. This latent heat is then expelled from the system when the fluid vapor condenses back to liquid form in the remote heat sink. Water is a particularly useful fluid to use in two-phase systems because it is cheap, has a high heat (or enthalpy) of vaporization and boils at a temperature that is well suited to cooling integrated circuits.

While a conventional microchannel heat exchanger as described above can effectively cool an integrated circuit die, conventional microchannel heat exchangers are expensive to manufacture because the microfabrication techniques used to create the microchannels such as deep reactive ion etching or electro-discharge machining are expensive to implement and have low processing throughput.

### BRIEF DESCRIPTION OF THE DRAWINGS

The foregoing aspects of this invention will become more readily appreciated by reference to the following detailed description, when taken in conjunction with the accompanying drawings, wherein like reference numerals refer to like parts throughout the various views unless otherwise specified. In the drawings:

FIG. 1 is a cross-section view of a folded fin microchannel heat exchanger in accordance with an embodiment of the invention;

FIG. 2 is a cross-section view of an integrated thermal management assembly including a folded fin microchannel heat exchanger coupled to an integrated circuit (IC) die using a thermal interface material and fasteners in accordance with an embodiment of the invention;

FIG. 3 is a cross-section view of an integrated thermal management assembly including a folded fin microchannel heat exchanger coupled to an IC die using solder in accordance with an embodiment of the invention;

FIG. 4 is a cross-section view of an integrated thermal management assembly including a folded fin microchannel heat exchanger coupled to an IC die using a thermal adhesive in accordance with an embodiment of the invention;

FIG. 5 is a block diagram of a mobile computer system employing a closed loop two-phase cooling system including a folded fin microchannel heat exchanger in accordance with an embodiment of the invention;

FIG. 6 is a schematic diagram of a closed loop cooling system employing a folded fin microchannel heat exchanger in accordance with an embodiment of the invention;

FIG. 7a is a plan view of a folded fin microchannel heat exchanger in accordance with an embodiment of the invention including parameters that define the configuration of the heat exchanger;

FIG. 7b is a cross section view illustrating further details of the channel configuration parameters of FIG. 7a in accordance with an embodiment of the invention; and

FIG. 8 is a flow diagram representing implementation of a method for cooling ICs using a folded fin microchannel heat exchanger in accordance with an embodiment of the invention

### DETAILED DESCRIPTION

Embodiments of folded fin microchannel heat exchanger apparatus, cooling systems employing the same and methods for cooling electronic components using the same are described. In the following description, numerous specific details such as cooling apparatus and system implementations, types and interrelationships of cooling apparatus and system components, and particular embodiments of folded fin microchannel heat exchangers are set forth in order to provide a more thorough understanding of the present invention. It will be appreciated, however, by one skilled in the art that embodiments of the invention may be practiced without such specific details or by utilizing, for example, different embodiments of folded fin microchannel heat exchangers. In other instances, methods for manufacturing folded fin heat exchangers or specific mechanical details for implementing cooling apparatus or systems, for example, have not been shown in detail in order not to obscure the embodiments of the invention. Those of ordinary skill in the art, with the included descriptions will be able to implement appropriate functionality without undue experimentation.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. Moreover, the particular features, structures, or characteristics may be combined in any suitable manner in one or more embodiments.

A number of figures show block diagrams of apparatus and systems comprising folded fin microchannel heat exchangers, in accordance with embodiments of the invention. One or more figures show flow diagrams illustrating operations for making or using folded fin microchannel heat exchangers likewise in accordance with embodiments of the invention. The operations of the flow diagrams will be described with references to the systems/apparatus shown in the block diagrams. However, it should be understood that the operations of the flow diagrams could be performed by embodiments of systems and apparatus other than those discussed with reference to the block diagrams, and embodiments discussed with reference to the systems/apparatus could perform operations different than those discussed with reference to the flow diagrams.

### Folded Fin Microchannel Heat Exchanger

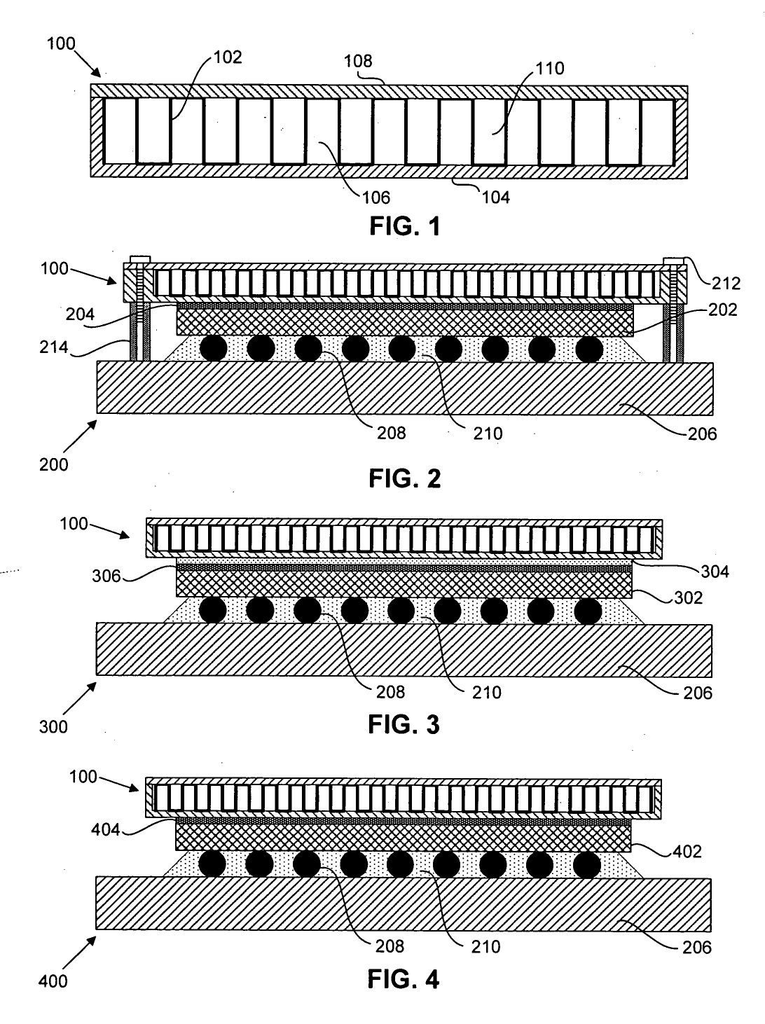

FIG. 1 illustrates in cross-sectional view one embodiment of a folded fin microchannel heat exchanger 100 in accordance with the invention. Heat exchanger 100 includes a metal folded fin 102 housed within a metal base 104 to define channels 106 between folded fin 102 and base 104. A cover plate 108 encloses folded fin 102 within base 104 such that a hermetic seal is formed between base 104 and plate 108 and such that channels 110 are defined between folded fin 102 and plate 108. For illustration purposes the size and form of folded fin 102 and the dimensions of channels 106 and 110 are exaggerated for clarity. In operation, heat exchanger 100 acts as a thermal mass to absorb heat conducted from integrated circuits. Details of exemplary configurations for channels 106 and 110 are discussed below with reference to FIGS. 6a and 6b. Folded fin 102 and base 104 are formed using well-known techniques. For example, folded fin 102 can be formed by folding metal sheet stock and base 104 can be formed by stamping it out of metal sheet stock.

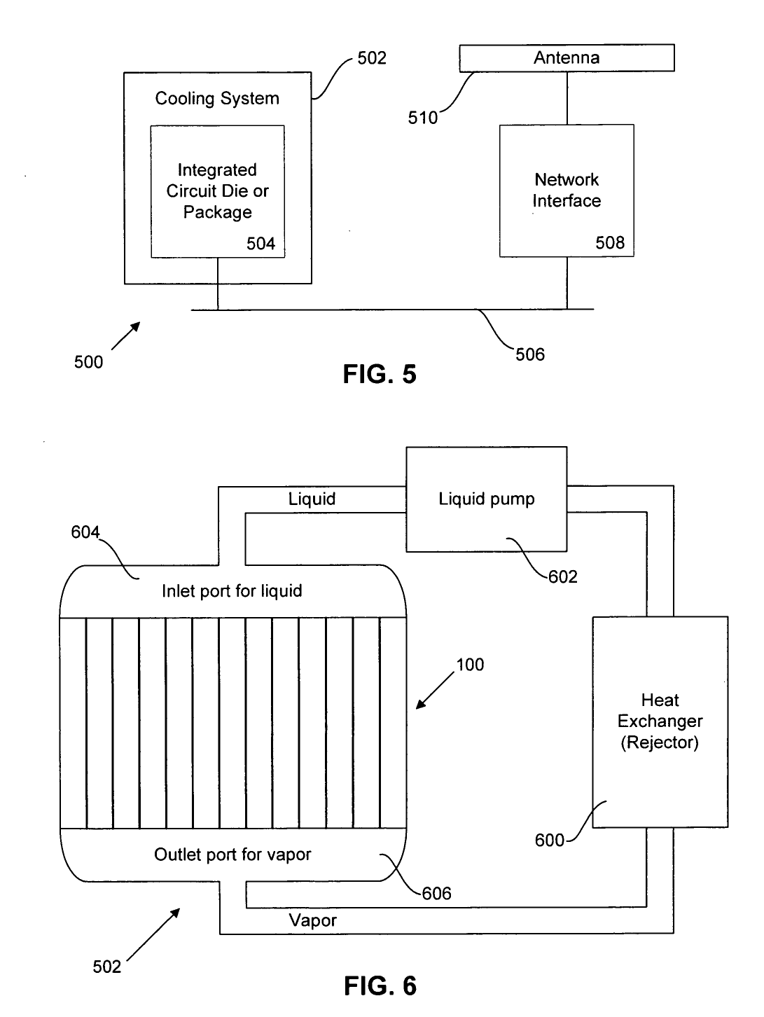

Channels 106 and 110 together comprise the microchannels within heat exchanger 100 through which a fluid such as water can be pumped from an inlet manifold and an outlet manifold (not shown in FIG. 1 but discussed below with reference to FIGS. 5 and 6). In one embodiment, folded fin 102, base 104 and plate 108 are formed from copper allowing folded fin 102 and plate 108 to be brazed to base 104 using standard copper brazing techniques. The invention is, however, not limited in this respect and any technique of containing folded fin 102 within base 104 and plate 108 may be utilized such that channels 106 and 110 are defined and such that a hermetic seal is formed between base 104 and plate 108. For example, plate 108 could be soldered or brazed to base 104 such that folded fin 102 is contained within the space formed between base 104 and plate 108 without directly attaching folded fin 102 to base 104. Alternatively, plate 108 could be affixed to base 104 using any means capable of forming a hermetic seal between plate 108 and base 104 such as adhesives or o-ring seals in combination with clips or other fasteners.

FIG. 2 illustrates, in accordance with an embodiment of the invention, an integrated thermal management assembly 200 comprising folded fin microchannel heat exchanger 100 coupled thermally to an integrated circuit (IC) die 202 via a Thermal Interface Material (TIM) 204 and coupled operatively to a substrate 206 to which the IC die 202 is flip-bonded by a plurality of solder bumps 208. TIM layer 204 serves several purposes; first, it provides a conductive heat transfer path from die 202 to heat exchanger 100 and, second, because TIM layer 204 is very compliant and adheres well to both the die 202 and heat exchanger 100, it acts as a flexible buffer to accommodate physical stress resulting from differences in the coefficients of thermal expansion (CTE) between die 202 and heat exchanger 100.

Heat exchanger 100 is physically coupled to substrate 206 through a plurality of fasteners 212 each one of the plurality of fasteners 212 coupled to a respective one of a plurality of standoffs 214 mounted on substrate 206. In addition, an epoxy underfill 210 is typically employed to strengthen the interface between die 202 and substrate 206. The illustrated fasteners 212 and standoffs 214 are just one example of a number of well known assembly techniques that can be used to physically couple heat exchanger 100 to die 202. In another embodiment, for example, heat exchanger 100 is coupled to die 202 using clips mounted on substrate 206 and extending over heat exchanger 100 in order to press heat exchanger 100 against TIM layer 204 and die 202.

FIG. 3 illustrates, in accordance with an embodiment of the invention, an integrated thermal management assembly 300 comprising a metallic folded fin microchannel heat exchanger 100 coupled thermally and operatively to an IC die 302 by solder 304 and solderable material 306. Soldering heat exchanger 100 to die 302 eliminates the need for the fasteners and standoffs of assembly 200 of FIG. 2. As above, an epoxy underfill 210 is typically employed to strengthen the interface between die 302 and the substrate 206 that die 302 is flip-bonded to by a plurality of solder bumps 208.

Generally, solderable material 306 may comprise any material to which the selected solder will bond. Such materials include but are not limited to metals such as copper (Cu), gold (Au), nickel (Ni), aluminum (Al), titanium (Ti), tantalum (Ta), silver (Ag) and Platinum (Pt). In one embodiment, the layer of solderable material comprises a base metal over which another metal is formed as a top layer. In another embodiment, the solderable material comprises a noble metal; such materials resist oxidation at solder reflow temperatures, thereby improving the quality of the soldered joints. In one embodiment, both heat exchanger 100 and solderable material 306 are copper.

Generally, the layer (or layers) of solderable material may be formed over the top surface of the die 302 using one of many well-known techniques common to industry practices. For example, such techniques include but are not limited to sputtering, vapor deposition (chemical and physical), and plating. The formation of the solderable material layer may occur prior to die fabrication (i.e., at the wafer level) or after die fabrication processes are performed.

In one embodiment solder 304 may initially comprise a solder preform having a pre-formed shape conducive to the particular configuration of the bonding surfaces. The solder preform is placed between the die and the metallic heat exchanger during a pre-assembly operation and then heated to a reflow temperature at which point the solder melts. The temperature of the solder and joined components are then lowered until the solder solidifies, thus forming a bond between the joined components.

FIG. 4 illustrates, in accordance with an embodiment of the invention, an integrated thermal management assembly 400 comprising a folded fin microchannel heat exchanger 100 coupled thermally and operatively to an IC die 402 by a thermal adhesive 404. Thermal adhesives, sometimes called thermal epoxies, are a class of adhesives that provide good to excellent conductive heat transfer rates. Typically, a thermal adhesive will employ fine portions (e.g., granules, slivers, flakes, micronized, etc.) of a metal or ceramic, such as silver or alumina, distributed within in a carrier (the adhesive), such as epoxy. One advantage obtained when using some types of thermal adhesives, such as alumina products, concerns the fact that these thermal adhesives are also good electrical insulators, thereby electrically isolating the die circuitry from the metallic folded fin microchannel heat exchanger.

A further consideration related to the embodiment of FIG. 4 is that the heat exchanger need not comprise a metal. In general, the heat exchanger may be made of any material that provides good conductive heat transfer properties. For example, a ceramic carrier material embedded with metallic pieces in a manner to the thermal adhesives discussed above may be employed for the heat exchanger. It is additionally noted that a heat exchanger of similar properties may be employed in the embodiments of FIGS. 2 and 3 if, in the case of the embodiment of FIG. 3, a layer of solderable material is formed over surface areas that are soldered to the IC die (i.e., the base of folded fin microchannel heat exchanger 100).

While FIGS. 2 thru 4 illustrate folded fin microchannel heat exchanger 100 thermally and operatively coupled to IC die 202, 302 and 402 respectively, the invention is not limited in this respect and one of ordinary skill in the art will appreciate that folded fin heat exchangers 100 can be thermally and operatively coupled to an IC package containing one or more IC die while remaining within the scope and spirit of the invention.

### Cooling Systems

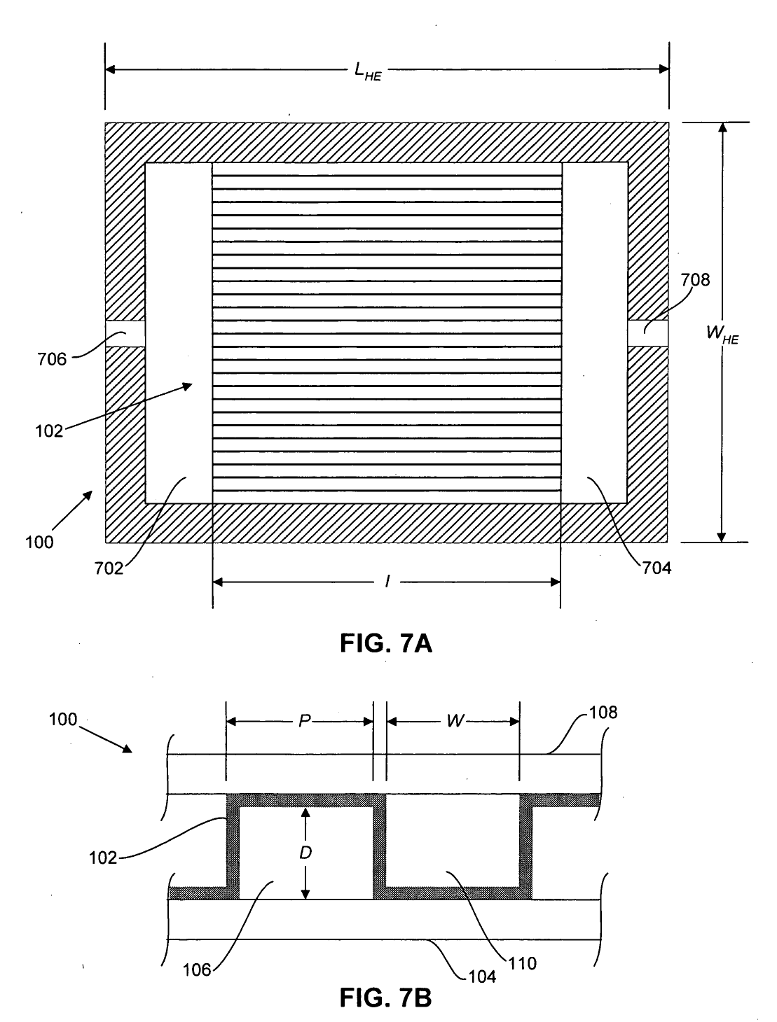

FIG. 5 illustrates one embodiment in accordance with the invention of a mobile computer system 500 having a closed loop two-phase cooling system 502 including a folded fin microchannel heat exchanger (not shown) coupled thermally and operatively to an IC die or package 504. System 500 includes a bus 506, which in an embodiment, may be a Peripheral Component Interface (PCI) bus, linking die 504 to a network interface 508 and an antenna 510. Network interface 508 provides an interface between IC die or package 504 and communications entering or leaving system 500 via antenna 510. The folded fin microchannel heat exchanger within cooling system 502 acts as a thermal mass to absorb thermal energy from, and thereby cool, IC die or package 504. Cooling system 502 is described in more detail below with respect to FIGS. 6, 7a and 7b. While the embodiment of system 500 is a mobile computer system, the invention is not limited in this respect and other embodiments of systems incorporating cooling systems utilizing folded fin microchannel heat exchangers in accordance with the invention include, for example, desktop computer systems, server computer systems and computer gaming consoles to name only a few possibilities.

FIG. 6 illustrates one embodiment in accordance with the invention of closed loop two-phase cooling system 500 having a folded fin microchannel heat exchanger coupled thermally and operatively to an IC die or package (not shown). System 500 includes a folded fin microchannel heat exchanger 100, a heat rejecter 600, and a pump 602. System 500 takes advantage of the fact, as discussed earlier, that a fluid undergoing a phase transition from a liquid state to a vapor state absorbs a significant amount of energy, known as latent heat, or heat of vaporization. This absorbed heat having been converted into potential energy in the form of the fluid's vapor state can be subsequently removed from the fluid by returning the vapor phase back to liquid. The folded fin microchannels, which typically have hydraulic diameters on the order of hundred-micrometers, are very effective for facilitating the phase transfer from liquid to vapor.

System 500 functions as follows. As the die circuitry generates heat, the heat is conducted into the folded fin microchannel heat exchanger 100. The heat increases the temperature of the heat exchanger 100 thermal mass, thereby heating the temperature of the walls in the folded fin microchannels. Liquid is pushed by pump 602 into an inlet port 604, where it enters the inlet ends of the folded fin microchannels. As the liquid passes through the microchannels, further heat transfer takes place between the microchannel walls and the liquid. Under a properly configured heat exchanger, a portion of the fluid exits the microchannels as a vapor at outlet port 606. The vapor then enters heat rejecter 600. The heat rejecter comprises a second heat exchanger that performs the reverse phase transformation as folded fin microchannel heat exchanger 100—that is, it converts the phase of the vapor entering at an inlet end back to a liquid at the outlet of the heat rejecter. The liquid is then received at an inlet side of pump 602, thus completing the cooling cycle.

In this manner system 500 acts to transfer the heat rejection process from the processor/die, which is typically somewhat centrally located within the chassis of a notebook computer, for example, to the location of the heat rejecter heat exchanger, which can be located anywhere within the chassis, or even externally.

### Folded Fin Microchannel Configurations

Plan and cross-section views illustrating folded fin microchannel heat exchanger configurations in accordance with the invention are shown in FIGS. 7a and 7b, respectively. In general, the channel configuration for a particular implementation will be a function of the heat transfer parameters (thermal coefficients, material thickness, heat dissipation requirements, thermal characteristics of working fluid), working fluid pumping characteristics (temperature, pressure, viscosity), and die and/or heat exchanger area. The goal is to achieve a two-phase working condition in conjunction with a low and uniform junction temperature and a relatively low pressure drop across the heat exchanger.

Example folded fin microchannel configuration parameters are shown in FIG. 7a and 7b. The parameters include a width W, a depth D, and a length l. Respective reservoirs 702 and 704 are fluidly coupled to an inlet 706 and outlet 708. In essence, the reservoirs function as manifolds in coupling the microchannels of folded fin 102 to incoming and outgoing fluid lines. If formed from copper, for example, folded fin 102, defining rectangular channels 106 and 110, can be brazed to copper base 104 formed, itself, by stamping from copper sheet stock. Brazing copper plate 108 to base 104 and adding inlet 706 and outlet 708 completes heat exchanger 100. Incorporating space for reservoirs 702 and 704 yields an overall length of the heat exchanger of L_{HE} and an overall width of W_{HE}.

Typically, the folded fin microchannels 106 and 110 will have a hydraulic diameter (e.g., channel width W) in the hundreds of micrometers (μm), although smaller microchannels may be employed having hydraulic diameters of 100 μm or less. Similarly, the depth D of the microchannels will be of the same order of magnitude. It is believed that the pressure drop is key to achieving low and uniform junction temperature, which leads to increasing the channel widths. However, channels with high aspect ratios (W/D) may induce flow instability due to the lateral variation of the flow velocity and the relatively low value of viscous forces per unit volume.

In an example of representative dimensions for a folded fin microchannel heat exchanger for cooling a 20 mm×20 mm die, 25 channels having a width w of 700 μm, a depth d of 300 μm and a pitch p of 800 μm are defined by a folded fin contained with a heat exchanger (thermal mass) 100 having an overall length L_{HE} of 30 mm and an overall width W_{HE} of 22 mm, with a channel length of 20 mm. The working fluid is water, and the liquid water flow rate for the entire channel array is 20 ml/min. While these dimensions are representative of one embodiment of the invention, the invention is not limited in this respect and other folded fin microchannel heat exchanger dimensions may be utilized while remaining within the scope and spirit of the invention.

Generally, the pump 602 used in the closed loop cooling system 500 employing folded fin microchannel heat exchangers 100 in accordance with the embodiments described herein may comprise electromechanical (e.g., MEMS-based) or electro-osmotic pumps (also referred to as “electric kinetic” or “E-K” pumps). Electro-osmotic pumps are advantageous over electromechanical pumps because they do not have any moving parts and hence are more reliable than electromechanical pumps. Since both of these pump technologies are known in the microfluidic arts, further details are not provided herein.

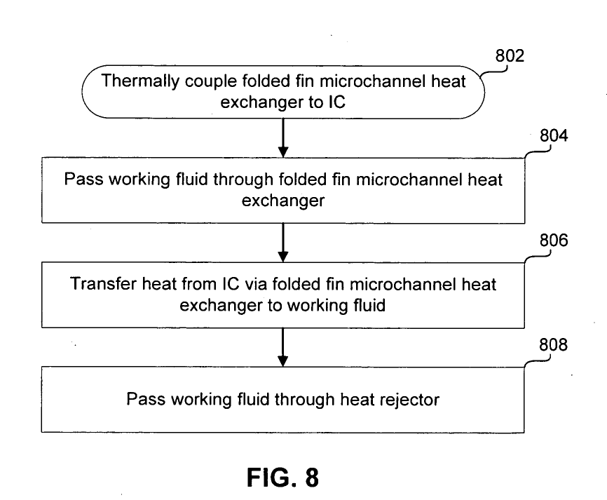

FIG. 8 illustrates a flow diagram representing implementation of a method for cooling ICs using a folded fin microchannel heat exchanger in accordance with an embodiment of the invention. In the embodiment of FIG. 8 the ICs being cooled include a processor IC and can include additional components such as platform chipset ICs, memory ICs, video ICs, co-processors or other ICs. Some or all of the additional ICs can be spatially separated from the processor IC or can be included in an IC package along with processor IC. In block 802, at least one folded fin microchannel heat exchanger is thermally coupled to a least one IC. In block 804, a working fluid such as water is passed through the folded fin microchannel heat exchanger. At block 806, heat is transferred from the IC into working fluid within the folded fin microchannel heat exchanger thereby converting a portion of the working fluid from liquid to vapor phase. Finally, at block 808, the working fluid exiting the folded fin microchannel heat exchanger is passed through a heat rejector where heat is removed from the working fluid converting the working fluid back to a liquid phase.

Thus, methods, apparatuses and systems of a folded fin microchannel heat exchanger have been described. Although the invention has been described with reference to specific exemplary embodiments, it will be evident that various modifications and changes may be made to these embodiments without departing from the broader spirit and scope of the invention. For example, while the method, apparatuses and systems for utilizing a folded fin microchannel heat exchanger are described in reference to the invention's use in a two-phase liquid cooling system, in other embodiments, such method and systems are applicable to use in a single-phase cooling system. Therefore, the specification and drawings are to be regarded in an illustrative rather than a restrictive sense.

1. An apparatus comprising:
a thermal mass having a cavity formed within the mass;
inlet and outlet ports formed within the thermal mass and coupling the cavity with regions outside the thermal mass; and
a folded fin located within the cavity, said folded fin defining, at least in part, a plurality of microchannels within the cavity.

2. The apparatus of claim 1 wherein the folded fin comprises aluminum.

3. The apparatus of claim 1 wherein the folded fin comprises copper.

4. The apparatus of claim 3 wherein the thermal mass comprises copper and wherein the folded fin is physically coupled to the thermal mass by brazing.

5. An apparatus comprising:
an integrated circuit (IC) die; and
a thermal mass coupled to the IC die, the thermal mass comprising:
a cavity; and
a folded fin located within the cavity, wherein the folded fin defines, at least in part, a plurality of microchannels within the cavity.

6. The apparatus of claim 5, further comprising
a solderable layer formed on the IC die; wherein the thermal mass is metallic and wherein the thermal mass is thermally and operatively coupled to IC die by the solderable layer.

7. The apparatus of claim 6, wherein the solderable layer is formed from at least one of the following metals: copper (Cu), gold (Au), nickel (Ni), aluminum (Al), titanium (Ti), tantalum (Ta), silver (Ag) and Platinum (Pt).

8. The apparatus of claim 6, wherein the solderable layer and the metallic thermal mass are made of substantially similar metals.

9. The apparatus of claim 5, wherein the thermal mass is thermally and operatively coupled to the IC die by a thermal adhesive disposed between the thermal mass and the surface of the IC die.

10. The apparatus of claim 5, wherein the thermal mass is thermally coupled to the IC die by a thermal interface material (TIM) layer.

11. The apparatus of claim 10, further comprising a substrate to which the IC die is flip-bonded.

12. The apparatus of claim 11, wherein the thermal mass is operatively coupled to the substrate via a plurality of fasteners.

13. The apparatus of claim 12, further comprising a plurality of standoffs physically coupled to the substrate and to which the plurality of fasteners are physically coupled.

14. An apparatus comprising:
an integrated circuit (IC) package, said IC package containing one or more IC dies; and
a thermal mass coupled to the IC package, the thermal mass comprising:
a cavity; and
a folded fin located within the cavity, the folded fin defining, at least in part, a plurality of microchannels within the cavity.

15. The apparatus of claim 14, further comprising:
a solderable layer formed on the IC package, wherein the thermal mass is metallic and wherein the thermal mass is thermally and operatively coupled to IC package by the solderable layer.

16. The apparatus of claim 15, wherein the solderable layer is formed from at least one of the following metals: copper (Cu), gold (Au), nickel (Ni), aluminum (Al), titanium (Ti), tantalum (Ta), silver (Ag) and Platinum (Pt).

17. The apparatus of claim 15, wherein the solderable layer and the metallic thermal mass are made of substantially similar metals.

18. The apparatus of claim 14, wherein the thermal mass is thermally and operatively coupled to the IC package by a thermal adhesive disposed between the thermal mass and the surface of the IC package.

19. The apparatus of claim 14, wherein the thermal mass is thermally coupled to the IC package by a thermal interface material (TIM) layer.

20. The apparatus of claim 19, further comprising a substrate to which the IC package is flip-bonded.

21. The apparatus of claim 20, wherein the thermal mass is operatively coupled to the substrate via a plurality of fasteners.

22. The apparatus of claim 21, further comprising a plurality of standoffs physically coupled to the substrate and to which the plurality of fasteners are physically coupled.

23. A system, comprising:
an integrated circuit (IC) die;
a folded fin microchannel heat exchanger operatively and thermally coupled to the IC die, the folded fin microchannel heat exchanger comprising:
a thermal mass having a cavity;
a folded fin located within the cavity, the folded fin defining, at least in part, a plurality of microchannels within the cavity; and
an inlet and an outlet, wherein the microchannels are fluidly coupled at one end to the inlet and at the other end to the outlet;
a pump, having an inlet and an outlet fluidly coupled to the inlet of the folded fin microchannel heat exchanger; and
a heat rejecter, having an inlet fluidly coupled to the outlet of the folded fin microchannel heat exchanger and an outlet fluidly coupled to the inlet of the pump, wherein the system employs a working fluid that transfers heat generated by the IC die to the heat rejecter using a two-phase heat exchange mechanism.

24. The system of claim 23, wherein the working fluid is water.

25. The system of claim 23, further comprising:
a solderable layer formed on the IC die, wherein the thermal mass is metallic and wherein the folded fin microchannel heat exchanger is operatively and thermally coupled to the IC die by the solderable layer.

26. The system of claim 25, wherein the solderable layer and the metallic thermal mass are made of substantially similar metals.

27. The system of claim 23, wherein the pump comprises an electro osmotic pump.

28. A system, comprising:
an integrated circuit (IC) package;
a folded fin microchannel heat exchanger operatively and thermally coupled to the IC package, the folded fin microchannel heat exchanger comprising:
a thermal mass having a cavity;
a folded fin located within the cavity, the folded fin defining, at least in part, a plurality of microchannels within the cavity; and
an inlet and an outlet, wherein the microchannels are fluidly coupled at one end to the inlet and at the other end to the outlet;
a pump, having an inlet and an outlet fluidly coupled to the inlet of the folded fin microchannel heat exchanger; and
a heat rejecter, having an inlet fluidly coupled to the outlet of the folded fin microchannel heat exchanger and an outlet fluidly coupled to the inlet of the pump, wherein the system employs a working fluid that transfers heat generated by the IC die to the heat rejecter using a two-phase heat exchange mechanism.

29. The system of claim 28, wherein the working fluid is water.

30. The system of claim 28, further comprising:
a solderable layer formed on the IC package, wherein the thermal mass is metallic and wherein the folded fin microchannel heat exchanger is operatively and thermally coupled to the IC package by the solderable layer.

31. The system of claim 30, wherein the solderable layer and the metallic thermal mass are made of substantially similar metals

32. The system of claim 28, wherein the pump comprises an electro osmotic pump.

33. A system comprising:
an integrated circuit (IC) die;
a network interface;
an antenna coupled to the network interface;
a bus, said bus coupling the IC die to the network interface; and
a thermal mass coupled to the IC die, the thermal mass comprising:
a cavity; and
a folded fin located within the cavity, wherein the folded fin defines, at least in part, a plurality of microchannels within the cavity.

34. The system of claim 33, further comprising
a solderable layer formed on the IC die; wherein the thermal mass is metallic and wherein the thermal mass is thermally and operatively coupled to IC die by the solderable layer.

35. The system of claim 34, wherein the solderable layer is formed from at least one of the following metals: copper (Cu), gold (Au), nickel (Ni), aluminum (Al), titanium (Ti), tantalum (Ta), silver (Ag) and Platinum (Pt).

36. The apparatus of claim 34, wherein the solderable layer and the metallic thermal mass are made of substantially similar metals.

37. The apparatus of claim 33, wherein the thermal mass is thermally and operatively coupled to the IC die by a thermal adhesive disposed between the thermal mass and the surface of the IC die.

38. The apparatus of claim 33, wherein the thermal mass is thermally coupled to the IC die by a thermal interface material (TIM) layer.

39. The apparatus of claim 38, further comprising a substrate to which the IC die is flip-bonded.

40. The apparatus of claim 39, wherein the thermal mass is operatively coupled to the substrate via a plurality of fasteners.

41. The apparatus of claim 40, further comprising a plurality of standoffs physically coupled to the substrate and to which the plurality of fasteners are physically coupled.

42. A system comprising:
an integrated circuit (IC) package, said IC package containing one or more IC dies;
a network interface;
an antenna coupled to the network interface;
a bus, said bus coupling the IC package to the network interface; and
a thermal mass coupled to the IC package, the thermal mass comprising:
a cavity; and
a folded fin located within the cavity, wherein the folded fin defines, at least in part, a plurality of microchannels within the cavity.

43. The system of claim 42, further comprising
a solderable layer formed on the IC package; wherein the thermal mass is metallic and wherein the thermal mass is thermally and operatively coupled to IC package by the solderable layer.

44. The system of claim 43, wherein the solderable layer is formed from at least one of the following metals: copper (Cu), gold (Au), nickel (Ni), aluminum (Al), titanium (Ti), tantalum (Ta), silver (Ag) and Platinum (Pt).

45. The system of claim 43, wherein the solderable layer and the metallic thermal mass are made of substantially similar metals.

46. The system of claim 42, wherein the thermal mass is thermally and operatively coupled to the IC package by a thermal adhesive disposed between the thermal mass and the surface of the IC package.

47. The system of claim 42, wherein the thermal mass is thermally coupled to the IC package by a thermal interface material (TIM) layer.

48. The system of claim 47, further comprising a substrate to which the IC package is flip-bonded.

49. The system of claim 48, wherein the thermal mass is operatively coupled to the substrate via a plurality of fasteners.

50. The system of claim 49, further comprising a plurality of standoffs physically coupled to the substrate and to which the plurality of fasteners are physically coupled.

51. A method; comprising:
thermally coupling at least one folded fin microchannel heat exchanger to at least one IC;
passing a working fluid through the at least one folded fin microchannel heat exchanger;
transferring heat produced by the at least one IC via that IC's at least one folded fin microchannel heat exchanger to the working fluid to convert a portion of the working fluid passing through the folded fin microchannels in the at least one folded fin microchannel heat exchanger from a liquid to a vapor phase; and
passing the working fluid exiting the at least one folded fin microchannel heat exchanger through a heat rejecter, wherein the vapor phase portion of the working fluid is converted back to a liquid phase.

52. The method of claim 5 1, wherein the at least one IC includes a processor IC and at least one additional IC from the following group: a platform chipset IC, a video IC, a memory IC and a co-processor IC.

53. The method of claim 5 1, wherein the working fluid comprises water.

54. The method of claim 5 1, wherein the working fluid is passed through the at least one microchannel heat exchanger and the heat rejecter via a electro-osmotic pump.

55. The method of claim 51, wherein the heat rejecter comprises a channeled heat sink including a plurality of hollow heat sink fins having respective channels defined therein.

56. The method of claim 51, wherein the heat rejecter comprises a folded fin microchannel heat exchanger.
